(19) United States
(12) Patent Application Publication
(10) Pub. No.: US 2005/0208684 A1
(43) Pub. Date: Sep. 22, 2005

(54) Manufacturing method of semiconductor device

(75) Inventors: Naoki Yamada, Sakado (JP); Takeshi Makiuchi, Hitachi (JP)

Correspondence Address: Stanley P. Fisher;Reed Smith LLP, Suite 1400, 3110 Fairview Park Drive, Falls Church, VA, 22042-0681, US

(73) Assignee: Trecenti Technologies, Inc.

(21) Appl. No.: 11/037,168

(22) Filed: Jan. 19, 2005

(30) Foreign Application Priority Data
Mar. 19, 2004 (JP) JP2004-80621

(51) Int. Cl. H01L 21/00; H01L 21/66; G01R 31/26

(52) U.S. Cl. 438/14

(57) ABSTRACT

In a trial production process from a design process to an actual manufacturing process of semiconductor devices, a pre-process of a pad matrix wafer with simpler configuration than a prototype wafer is completed before a pre-process of the prototype wafer is completed, and data of conditions and evaluations to be used in a test process and a post-process subsequent to the pre-process of the prototype wafer is created by using the pad matrix wafer. Therefore, the data of conditions and evaluations used in the process subsequent to the pre-process can be prepared and the design modifications of various devices used in the process subsequent to the pre-process can be finished before the post-process of the prototype wafer is started. Therefore, a smooth transition from the pre-process to the subsequent processes of the prototype can be achieved, and the delivery time of semiconductor devices can be shortened.

### CROSS-REFERENCE TO RELATED APPLICATION

The present application claims priority from Japanese Patent Application JP 2004-080621 filed on Mar. 19, 2004, the content of which is hereby incorporated by reference into this application.

### TECHNICAL FIELD OF THE INVENTION

The present invention relates to a technique for manufacturing a semiconductor device. More particularly, it relates to a technique which is effective when applied to the setting of various conditions to be used in the process subsequent to the pre-process in the manufacturing process of a semiconductor device.

### BACKGROUND OF THE INVENTION

Semiconductor devices are mass-produced and shipped through several steps such as an initial development planning, various design processes, reticle work process, and trial and evaluation process. In the trial and evaluation process, a prototype is produced by using a reticle produced through the reticle work process in a trial production line or a mass-production line. In this stage, the basic functions and performances are checked, the prototype is produced in consideration of the variation in the mass-production so as to obtain the yield data, the margin of characteristics and performances, and reliability, and also, improvements and modifications are performed. When it is determined that the results of the trial production and evaluation sufficiently meet the requirements of the mass-production, the mass-production of the device will be started.

The above-mentioned prototype is produced in such a way that a wafer for prototype is prepared first, on which chips are formed through the same pre-process as that in the product manufacturing, and then the same wafer test process and post-process as those in the product manufacturing are performed. The wafer test process for producing the prototype requires various positional data of pads on a prototype wafer, optimum positional data in the height direction of a probe applied to the pad, and arrangement data of chips on a wafer for prototype. In addition, the post-process needs the evaluation of dicing conditions, the evaluation of assembly conditions (die bonding, flip chip bonding, and wire bonding), and the evaluation of contact conditions with package sockets for a final package test performed after the assembly. Those data are created by using a wafer for prototype produced through the same pre-process as that in the product manufacturing.

A technique for setting the measurement conditions at the time of probing the chips of a semiconductor wafer is described in Japanese Patent Application Laid-Open No. 8-37213.

### SUMMARY OF THE INVENTION

Meanwhile, the lead time from the permission by customers to an offer of an initial prototype has become shorter and shorter recently. So, the time required for setting various conditions and evaluations to be used in the wafer test and the post-process of a wafer for prototype has not been negligible for the reduction of the lead time for shipment of the prototype. In particular, although a large scale integrated circuit (LSI) intended for a specific system such as an application specific IC (ASIC) requires much time for design and development, it tends to be obsolete rapidly and its life cycle is short in some cases. Therefore, what matters is how a cycle time is shortened to make delivery quicker. However, in the above-mentioned methods, after a pre-process of a wafer for prototype is completed through the same pre-process as that in the product manufacturing, conditions and evaluation data required in the wafer test process and the post-process are created by using the wafer for prototype, and also, the debugging of a probe card used in the process subsequent to the pre-process of the prototype wafer and the condition setting and adjustment of the design failure of various assembly devices are performed by using the wafer for prototype. Therefore, the shipment of the prototype is delayed and consequently the shortening of the delivery time of semiconductor devices is prevented.

An object of the present invention is to provide a technique capable of shortening the delivery time of a semiconductor device.

The above and other objects and novel characteristics of the present invention will be apparent from the description and the accompanying drawings of this specification.

The typical ones of the inventions disclosed in this application will be briefly described as follows.

That is, the present invention comprises a step of providing a second wafer, which is produced in a pre-process having a fewer number of processes than a pre-process of a first wafer and has chips and external terminals arranged in the same manner as those of the first wafer, before providing the first wafer produced through the same pre-process as a product wafer.

The effect obtained by the representative one of the inventions disclosed in this application will be briefly described as follows.

That is, the delivery time of semiconductor devices can be shortened because, before providing the first wafer, conditions and evaluation data required in the process subsequent to the pre-process of the first wafer can be created and the debugging of various devices used in the process subsequent to the pre-process of the first wafer and the correction of a design failure can also be performed by using the second wafer.

### BRIEF DESCRIPTIONS OF THE DRAWINGS

FIG. 1 is a production flow chart of the semiconductor device according to an embodiment of the present invention;

FIG. 2 is an explanatory diagram for explaining timings of manufacturing the first and second wafers in the manufacturing process of the semiconductor device according to an embodiment of the present invention;

FIG. 3 is a general plan view of an example of the first wafer;

FIG. 4 is an enlarged plan view of the main part of the first wafer shown in FIG. 3;

FIG. 5 is a cross-sectional view of the main part of an example of the first wafer shown in FIGS. 3 and 4;

FIG. 6 is a general plan view of an example of the second wafer;

FIG. 7 is an enlarged plan view of the main part of the second wafer shown in FIG. 6;

FIG. 8 is a cross-sectional view of the main part of an example of the second wafer shown in FIGS. 6 and 7;

FIG. 9 is an equivalent circuit diagram of a circuit of the second wafer shown in FIG. 8;

FIG. 10 is a simplified equivalent circuit diagram of FIG. 9;

FIG. 11 is a circuit diagram of an input circuit section of the semiconductor device;

FIG. 12 is a cross-sectional view of the main part of the second wafer at the time of the open contact test and the short contact test;

FIG. 13 is a DC equivalent circuit diagram of the circuit of the second wafer at the time of the open contact test;

FIG. 14 is an explanatory diagram of the current monitor method with fixed voltage at the time of the open contact test;

FIG. 15 is an explanatory diagram of the voltage monitor method with fixed current at the time of the open contact test;

FIG. 16 is a DC equivalent circuit diagram of the circuit of the second wafer at the time of the short contact test;

FIG. 17 is an explanatory diagram of the current monitor method with fixed voltage at the time of the short contact test;

FIG. 18 is an explanatory diagram of the voltage monitor method with fixed current at the time of the short contact test;

FIG. 19 is a cross-sectional view of the main part in the manufacturing process of the second wafer;

FIG. 20 is a cross-sectional view of the main part of the second wafer in the manufacturing process subsequent to FIG. 19;

FIG. 21 is a cross-sectional view of the main part of the second wafer in the manufacturing process subsequent to FIG. 20;

FIG. 22 is a cross-sectional view of the main part of the second wafer in the manufacturing process subsequent to FIG. 21;

FIG. 23 is a cross-sectional view of the main part of the second wafer in the manufacturing process subsequent to FIG. 22;

FIG. 24 is a cross-sectional view of the main part of the second wafer in the manufacturing process subsequent to FIG. 23;

FIG. 25 is a cross-sectional view of the main part of the second wafer in the manufacturing process subsequent to FIG. 24;

FIG. 26 is a cross-sectional view of the main part of the second wafer in the manufacturing process subsequent to FIG. 25;

FIG. 27 is a cross-sectional view of the main part of the second wafer in the manufacturing process subsequent to FIG. 26;

FIG. 28 is a general perspective view of the second wafer before a rear surface polishing process;

FIG. 29 is a general perspective view of the second wafer in FIG. 28 after the rear surface polishing process;

FIG. 30 is a general perspective view of the second wafer after a dicing process;

FIG. 31 is a general perspective view of an example when the chip cut from the second wafer is mounted on the chip-mounting region of a lead frame;

FIG. 32 shows a general perspective view of an example of a chip cut from the second wafer after the wire-bonding and the encapsulating process;

FIG. 33 is a general perspective view of an example of the chip cut from the second wafer at the time of the final test after the encapsulating process;

FIG. 34 is an explanatory diagram of an example of the manufacturing process of the first wafer;

FIG. 35 is a cross-sectional view of the main part of an example of the first wafer in the manufacturing process of the semiconductor devices according to another embodiment of the present invention;

FIG. 36 is a cross-sectional view of the main part of an example of the second wafer used in the manufacturing process of the semiconductor device with the configuration shown in FIG. 35;

FIG. 37 is a general plan view of an example of the first wafer in the manufacturing process of the semiconductor device according to another embodiment of the present invention;

FIG. 38 is a general plan view of an example of the first wafer after a relocation wiring layer forming process;

FIG. 39 is a cross-sectional view of the main part of an example the first wafer shown in FIG. 38;

FIG. 40 is a general plan view of an example of the first wafer after a solder bump electrode forming process subsequent to FIG. 38;

FIG. 41 is a cross-sectional view of the main part of an example of the first wafer shown in FIG. 40; and

FIG. 42 is a cross-sectional view of the main part of an example of the second wafer used in the manufacturing process of the semiconductor device with the configuration shown in FIG. 41.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, components having the same function are denoted by the same reference symbols throughout the drawings for describing the embodiments, and the repetitive description thereof is omitted.

Also, a wafer for a product (hereinafter referred to as a product wafer) is the wafer from which the chips for the product are formed. A wafer for prototype (hereinafter referred to as a prototype wafer) is the wafer from which the chips for the prototype used for producing the product wafer are formed. The prototype wafer that has completed the pre-process through the same pre-process as the product wafer (including cases where the number of processes may increase or decrease a little bit than the pre-process of the product wafer) is called also a full process wafer (first wafer). The pre-process is called a wafer process, diffusion process, or wafer fabrication, and is the process in which elements and circuits are formed on a semiconductor substrate (hereinafter referred to as a substrate) so as to be ready for an electrical test with probes. The pre-process includes deposition process, impurity introduction (diffusion or ion implantation) process, photolithography process, etching process, metallizing process, cleaning process, and inspection process between each of the processes. The wafer test process is also called a G/W (Good chip/Wafer) check process in which each chip formed on the wafer is electrically checked. The post-process (assembly process) is a process after the wafer test process, where chips are stored in an encapsulating member (package) to complete the product. The post-process includes an assembly/finish process, selection/Burn-in Test (BT) process, and inspection process. The assembly/finish process includes a rear surface polishing process, dicing process, chip bonding process, wire bonding process (or flip chip bonding process) and encapsulating process.

The embodiments of the present invention will be described below in detail with reference to the drawings.

### First Embodiment

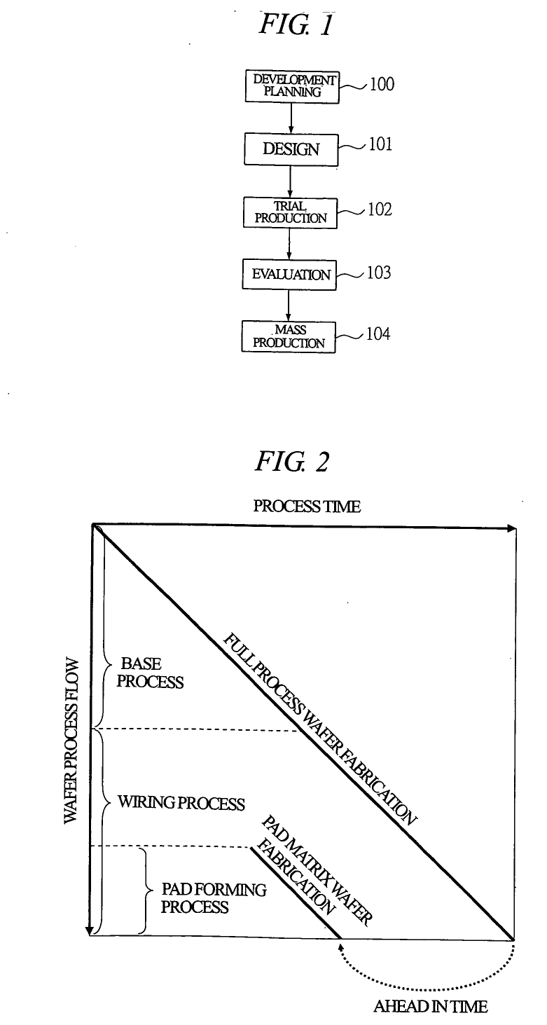

FIG. 1 shows a production flow chart of the semiconductor device according to a first embodiment.

First, this flow starts from a development planning 100 of products and moves to a design process 101. In the design process 101, a functional design, logical design, circuit design, device process design, and mask design for integrated circuit are performed in this order. In the functional design, logical design, and circuit design, a computer aided design (CAD) system is used to create data for product design, perform various verifications, and ensure and adjust the functions and performances based on simulation. In the device process design, experiments and data collection are repeated in consideration of a technical level for the mass production of the product (minimum dimensions, device structure, processes, manufacturing devices, production line and others) by using an element unit level and a small-scale Integrated circuit (IC) to determine the conditions. On the basis of those results, “design rule” and “manufacturing conditions” are determined. In the mask design, a mask pattern for forming an integrated circuit is designed based on the “design rule” by the use of the CAD system, and on the basis of the design data, a mask pattern is formed on a mask substrate to produce a mask (highest concept including reticle). In a trial production process 102 and an evaluation process 103, a prototype is produced in a trial production line or a mass-production line by using the above-mentioned mask. In this stage, the basic functions and performances of the semiconductor devices are checked, the prototype is produced in consideration of the variation at the time of mass production to obtain yield data, margin of characteristics and performances, and reliability, and also, the improvements and modifications thereof are performed as well. The flow moves to a mass production process 104 for the first time when it has been determined that the results of the trial and the evaluation can sufficiently meet the requirements of the mass-production.

For the meantime, in a typical trial production process of semiconductor devices, after the finish of the pre-process for the prototype wafer (full process wafer), by using the prototype wafer, conditions and data to be used in a testing process and the post-process are created, design of a probe card (wire routing of a probe card and placement of a probe) to be used in the testing process after the pre-process of the prototype wafer is corrected (debugged) in accordance with design specifications of semiconductor devices (a physical layout and dimensions of external terminals and signal layout are varied depending on products), setting conditions for various assembly devices are modified to meet the manufacturing conditions of semiconductor devices, and various design failures are confirmed and corrected. Therefore, the shipment of the prototype tends to significantly delay in some cases. In particular, a debugging work of the probe card is a troublesome job that takes much time and labor, which prevents the shortening of delivery time of semiconductor devices.

In the first embodiment, as shown in FIG. 2, the pre-process of a pad matrix wafer (second wafer) with a simpler configuration than the prototype wafer is finished prior to the finish of the pre-process of the prototype wafer (full process wafer), and the conditions and evaluation data to be used for a wafer test process and the post-process subsequent to the pre-process of the prototype and the product wafer are created by the use of the pad matrix wafer. In addition, before the prototype wafer is moved to a process subsequent to the pre-process, various devices such as testing devices and assembly devices to be used after the pre-process of the prototype wafer are set to the design conditions optimum for the manufacture of the prototype and product. Then, in the processes subsequent to the pre-process of the prototype wafer, various processes are performed by using the conditions and evaluation data created by the use of the pad matrix wafer. The condition data used in the wafer test process include, for example, positional data of various pads on the prototype wafer, optimum positional data in the height direction of the probe applied to the pad, and arrangement data of chips on the prototype wafer. Also, the evaluation data used in the post-process include, for example, rear surface polishing conditions, dicing conditions, assembly conditions (die bonding, flip chip bonding, and wire bonding) and contact conditions for package sockets to be used in a final package test after the assembly.

According to the first embodiment described above, by the condition setting and evaluation by using the pad matrix wafer, all or part of conditions and evaluation data used for a wafer test process and the post-process can be created in advance before the pre-process of the prototype wafer is completed. In addition, before the pre-process of the prototype wafer is completed, it is possible to debug design of the probe card in accordance with design specifications of the product by using the pad matrix wafer 1B. Further, it is also possible to modify the rear surface polishing conditions, dicing conditions, assembly conditions and final test conditions in accordance with manufacturing conditions of products, and confirm and correct various design failures before the pre-process of the prototype wafer is completed. Therefore, in the prototype production, the processes subsequent to the pre-process (i.e., a wafer test process and the post-process) can be smoothly started without waiting time. Consequently, a cycle time after the pre-process of the prototype wafer and a lead time for shipment of the prototype can be reduced, and therefore, the delivery time of semiconductor devices can be shortened significantly.

In a base process shown in FIG. 2, elements are formed on a substrate. In a pad forming process, external terminals of semiconductor devices are formed.

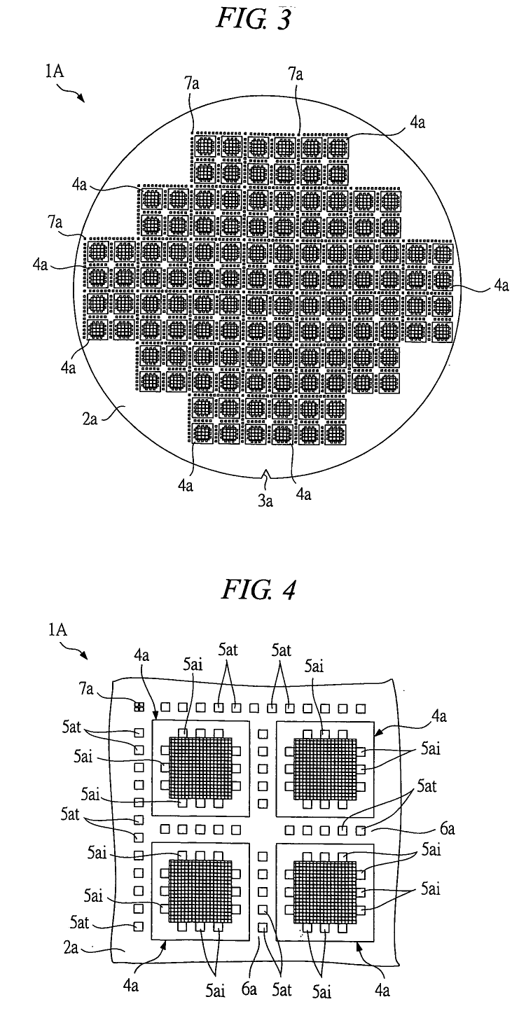

In the following, the aforementioned prototype wafer (full process wafer) will be described. FIG. 3 is a general plan view of an example of the prototype wafer (full process wafer) 1A. FIG. 4 is an enlarged plan view of the main part of the prototype wafer 1A shown in FIG. 3. Since the product wafer has the same configuration as the prototype wafer 1A, the description thereof is omitted.

The prototype wafer 1A is formed of a substrate 2a made of, for example, p-type silicon (Si) single crystal in the shape of a thin disk. The diameter of the prototype wafer 1A is not particularly limited but, for example, about 300 mm (12 inches). In a part of its periphery, a V-shaped notch 3a is formed to show its orientation. On the main surface of the prototype wafer 1A, a plurality of chips 4a are regularly arranged in all directions on FIG. 3. A desired IC in a prototype stage is formed on each chip 4a. As the desired IC, in addition to ASIC such as SoC, such memory circuits as dynamic random access memory (DRAM), static RAM (SRAM), and flash memory can be exemplified. In the region of internal circuits at the center of each chip 4a, elements and wires constituting the IC are formed. Also, in the region of peripheral circuits around the region of internal circuits of each chip 4a, a plurality of pads (external terminals) 5ai are regularly arranged along the periphery of the chip 4a.

Cut regions 6a called a dicing region or a scribing region are provided between the adjacent chips 4a. In the cut region 6a, a plurality of test element groups (TEG), pads (external terminals) 5at, and alignment marks 7a are provided. The TEG is a group of elements used for evaluating basic structure, physical properties, electrical characteristics, circuit operation, reliability, and yield in an element level and IC level. The pad 5at is an external terminal for TEG and electrically connected to TEG through wires. The alignment mark 7a serves as a positional reference of the chip 4a, and pads 5ai and 5at, and is provided for every four chips 4a.

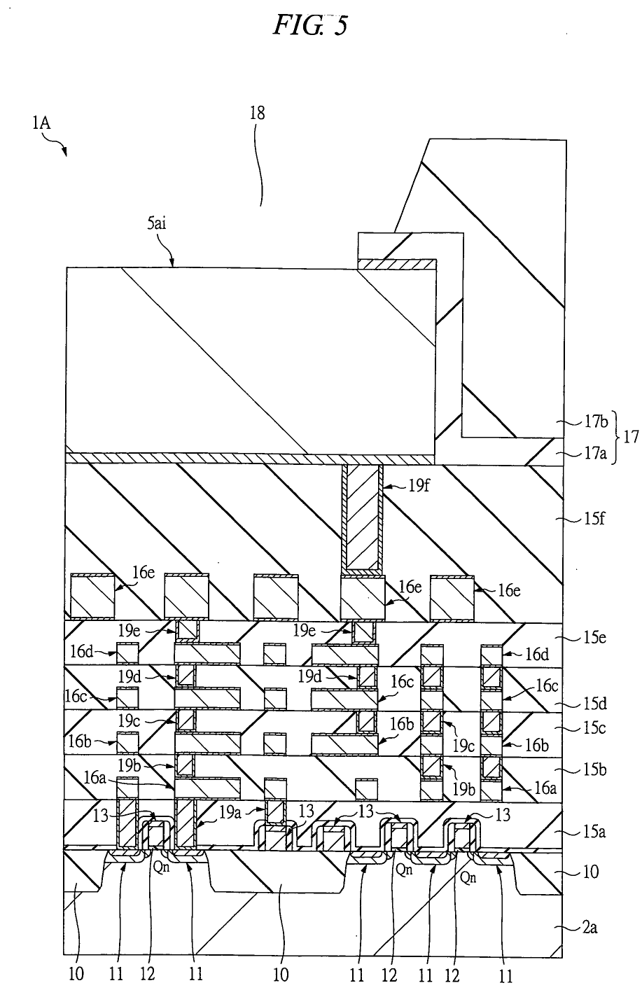

FIG. 5 is a cross-sectional view of the main part of the chip 4a of the prototype wafer 1A shown in FIGS. 3 and 4. On the main surface of the substrate 2a, a grooved isolation section 10 called shallow groove isolation (SGI) or shallow trench isolation (STI) is formed. In the active region defined by this isolation section 10, for example, n-channel MOSFET Qn is formed. The MOSFET Qn has n-type semiconductor regions 11 for a source and drain, a gate insulating film 12, and a gate electrode 13. The semiconductor region 11 is formed by introducing phosphorus (P) and arsenic (As) into the substrate 2a. A silicide layer is formed on the layer of the region 11. The gate insulating film 12 is made of, for example, silicon oxide (SiO₂). The gate electrode 13 is made by, for example, forming the silicide layer on low-resistance polysilicon. The elements formed on the substrate 2a are not limited to the n-channel MOSFET Qn, but may include passive elements such as resistors and capacitors in addition to active elements such as, for example, p-channel MOSFET, diodes, and others.

Insulating layers 15a to 15f and wiring layers 16a to 16e which are piled alternately in the thickness direction are formed on the main surface of the substrate 2a. The insulating layers 15a to 15f are made of, for example, silicon oxide. The wiring layers 16a to 16e are composed of a main wiring material and a barrier metal layer formed thereon and thereunder. The main materials of the wiring layers 16a to 16e are, for example, aluminum (Al) or aluminum alloy, and the barrier metal layer is formed of, for example, a single film of titanium nitride (TiN) or a laminated film of titanium nitride and titanium (Ti). The wiring layers 16a to 16e are formed by depositing the main wiring material and barrier metal layer, and then, patterning a conductive layer by an etching method using a resist film as an etching mask. On the top wiring layer, the pads 5ai and 5at are formed. The pads 5ai and 5at are formed of the same material and by the same method as the above-mentioned wiring layers 16a to 16e. Also, on the top wiring layer, a surface protection layer 17 is formed so as to cover the pads 5ai and 5at. In a part of the surface protection layer 17, an opening 18 is formed, through which a part of the pads 5ai and 5at is exposed. At the parts where the pads 5ai and 5at are exposed through the opening 18, the barrier metal layer is also removed to expose an underlying main wiring material. The surface protection layer 17 has protective layers 17a and 17b. The underlying protective layer 17a is made of, for example, silicon nitride (Si₃N₄), silicon oxide or a laminated layer thereof. The upper protective layer 17b is made of, for example, photosensitive polyimide resin. An electrical connection is established between the wires and substrates (or gate electrodes), between the wiring layers and between wires and pads through plugs 19a to 19f. The plugs 19a to 19f are formed in holes opened in the insulating layer, and have a main wiring material and a barrier metal layer formed on the side and bottom surfaces thereof. The main wiring material of the plugs 19a to 19f is metal such as tungsten (W), and the barrier metal layer is composed of a laminated layer of titanium (Ti) and titanium nitride.

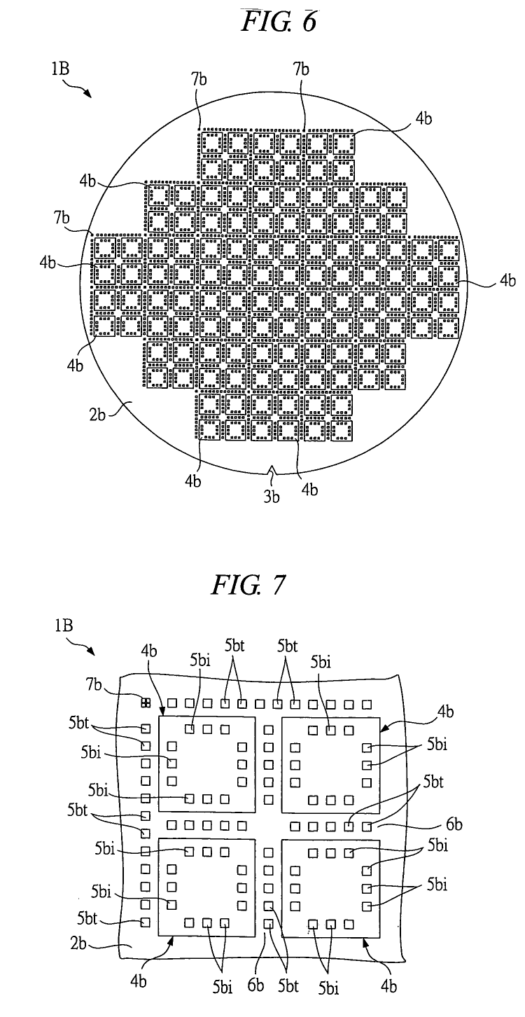

Next, the above-mentioned pad matrix wafer will be described. FIG. 6 shows a general plan view of an example of the pad matrix wafer (second wafer) 1B. FIG. 7 shows an enlarged plan view of the main part of the pad matrix wafer 1B shown in FIG. 6.

As stated above, the pad matrix wafer 1B is an auxiliary wafer required for producing the prototype and the product wafer, which is to be used for creating conditions and evaluation data used after the pre-process of the prototype wafer 1A, for debugging the design of the testing devices used after the pre-process of the prototype wafer 1A in accordance with design specifications of products, for setting the conditions of the assembly devices used after the pre-process of the prototype wafer 1A in accordance with fabrication conditions of the product wafer, and for confirming and correcting design failures. The substrate 2b of the pad matrix wafer 1B is made of, for example, p-type silicon (Si) single crystal similar to the prototype wafer 1A. The pad matrix wafer 1B has the same diameter and thickness as the prototype wafer 1A, and in a part of the periphery thereof, a notch 3b is formed similar to the prototype wafer 1A. Also on the main surface of the pad matrix wafer 1B, a plurality of chips 4b are regularly arranged in all directions on FIG. 6. The overall layout, position coordinate, quantity, and planar dimension of the chip 4b are the same as those of the chip 4a of the prototype wafer 1A. The mask used in the pre-process (exposure process) of the pad matrix wafer 1B is the same as that used in the pre-process of the prototype wafer 1A. However, the chips 4b of the pad matrix wafer 1B are produced in a fewer processes than those in the pre-process of the prototype wafer 1A. On the chip 4b, complicated circuits like the ICs of the chip 4a of the prototype wafer 1A are not formed, but simpler ones than those of the chip 4a of the prototype wafer 1A are formed. An example of a cross-sectional view of the chip 4b will be described later.

In the region of the chip 4b, a plurality of pads (external terminals) 5bi are arranged. The pads 5bi are parts corresponding to the pads 5ai of the prototype wafer 1A, and the overall layout, position coordinate, quantity, planar dimensions, materials and forming method of the pads 5bi are the same as those of the pads 5ai of the prototype wafer 1A. Further, a plurality of pads (external terminals) 5b and alignment marks 7b are placed in a cut region 6b around the chips 4b. The pads 5b and alignment marks 7b are parts corresponding to the pads 5at and the alignment marks 7a of the prototype wafer 1A, respectively. The overall layout, position coordinate, quantity, planar dimensions, materials and forming method of the pads 5bt, the alignment marks 7b, and the cut region 6b are the same as those of the pads 5at, the alignment marks 7a, and the cut region 6a of the prototype wafer 1A.

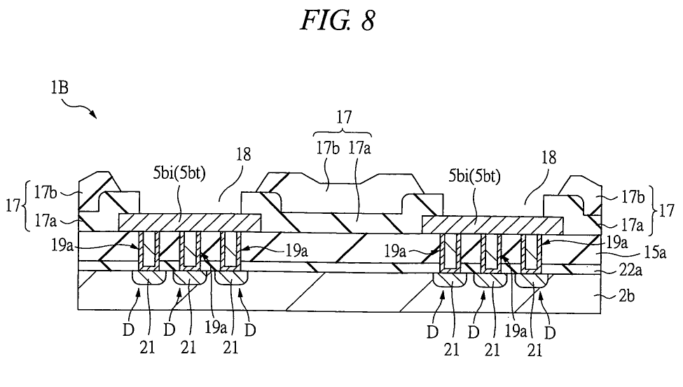

FIG. 8 is a cross-sectional view of the main part of the chip 4b (or the cut region 6b) of the pad matrix wafer 1B shown in FIGS. 6 and 7.

In the main surface of the p-type substrate 2b, a plurality of n-type semiconductor regions 21 are formed, thereby forming pn junction diodes D. On the main surface of the substrate 2b, insulating layers 22a and 15a are formed. The insulating layer 22a is made of, for example, silicon oxide. On the insulating layer 15a, the above-mentioned pads 5bi (or the pads 5bt) are formed. The pads 5bi (or the pads 5bt) are electrically connected to the n-type semiconductor regions 21 via the plugs 19a. On the insulating layer 15a, a surface protection layer 17 is formed so as to cover the pads 5bi and 5bt. In some parts of the surface protection layer 17, openings 18 are formed, through which the parts of the pads 5bi (or the pads 5bt) are exposed. The insulating layers 15a, plugs 19a, and the surface protection layer 17 have the same configuration as those in the prototype wafer 1A described above.

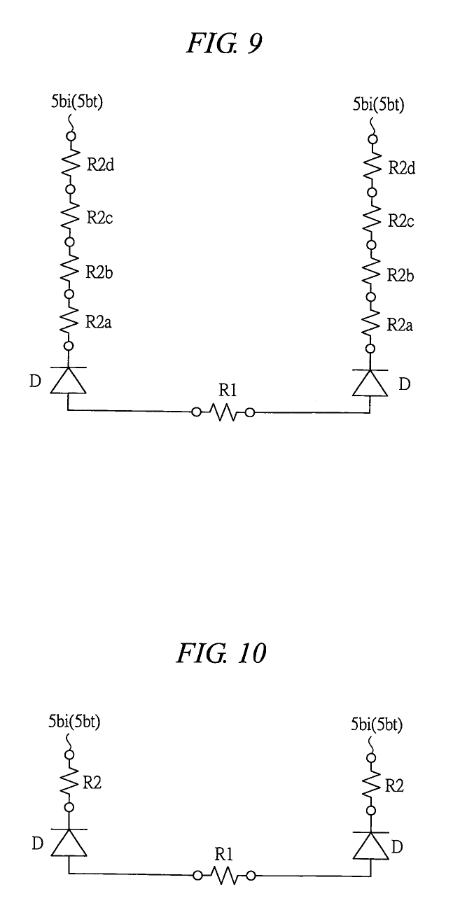

FIG. 9 shows a direct current (DC) equivalent circuit of the pad matrix wafer 1B. FIG. 10 shows a simplified equivalent circuit of FIG. 9. The pads 5bi are electrically connected to each other through resistors R1 and R2 (R2a to R2d) and the pn junction diodes D. In this case, the resistor R1 represents the resistance of the substrate 2b, the resistor R2a represents the diffusion resistance of the n-type semiconductor region 21, the resistor R2b represents the resistance of the barrier metal layer of the plug 19a, the resistor R2c represents the resistance of main wiring material of the plug 19a, and the resistor R2d represents the resistance of the pad 5bi (or the pad 5bt). The resistor R2 in FIG. 10 represents a total sum of the resistors R2a to R2d.

In the first embodiment, the current generated when a bias (voltage) is applied to the pn junction diode D (that is, a junction between the p-type substrate 2b and the n-type semiconductor region 21) is used to perform an open contact test and a short contact test described below. The open contact test is a test process for checking whether the probe of the probe card makes contact with the pads 5bi and 5bt of the pad matrix wafer 1B. The short contact test is a test process in which short-circuit of the pads 5bi and 5bt of the pad matrix wafer 1B is detected. Based on the measurements obtained in these test processes, evaluation and required data are created, and the debugging of the probe cards is performed.

In the test process using these pn junction diodes D, the principle of the protective diode formed on an input/output circuit section of the semiconductor device is applied. FIG. 11 shows a circuit diagram of the input circuit of the semiconductor device. A pad 5ci for input is electrically connected to an input of an input inverter circuit INV via the wire. Protective diodes Dp1 and Dp2 are electrically connected between the wire connecting the pad 5ci for input to the input inverter circuit INV and power supply wires LVcc and LVss. Protective diodes Dp1 and Dp2 are elements for protecting internal circuits from overvoltage such as static electricity, and are normally composed of the pn junction diodes formed on the substrate 2a. When a voltage higher than a power supply voltage Vcc is applied to the pad 5ci for input, a current I1 flows from the pad 5ci for input to the power supply wire LVcc through the protective diode Dp1. On the other hand, when a voltage lower than a reference voltage Vss is applied to the pad 5ci for input, a current I2 flows from the power supply wire LVss to the pad 5ci for input through the protective diode Dp2. In this manner, the input inverter circuit INV of the semiconductor device and the internal circuits at the latter stage are protected. The first embodiment applies the principle of the operation of such protective diodes Dp1 and Dp2. The detail principle of the open contact test and the short contact test using the pad matrix wafer 1B will be described below.

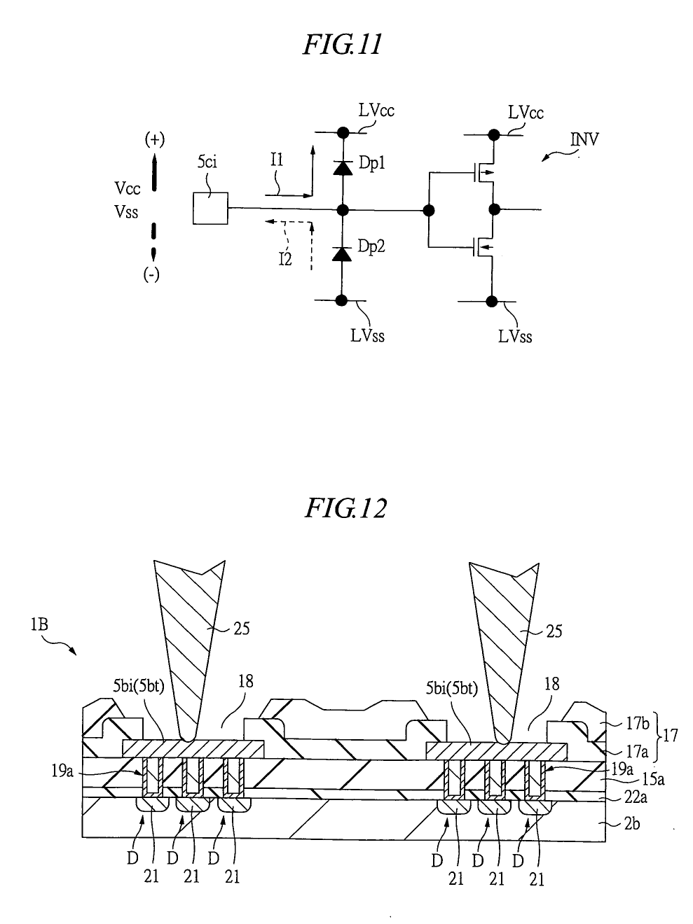

FIG. 12 shows a cross-sectional view of main part of the pad matrix wafer 1B at the time of the open contact test and the short contact test. In either of the test processes, a voltage fixed current monitor method (VFIM) and a current fixed voltage monitor method (IFVM) are provided. In FIG. 12, the pad 5bi (or the pad 5bt) on the left is taken as a measured pad, and the pad 5bi (or the pad 5bt) on the right is taken as a reference pad. The probes 25 of the probe card are touched on the measured and reference pads 5bi (or the pads 5bt) in the test process.

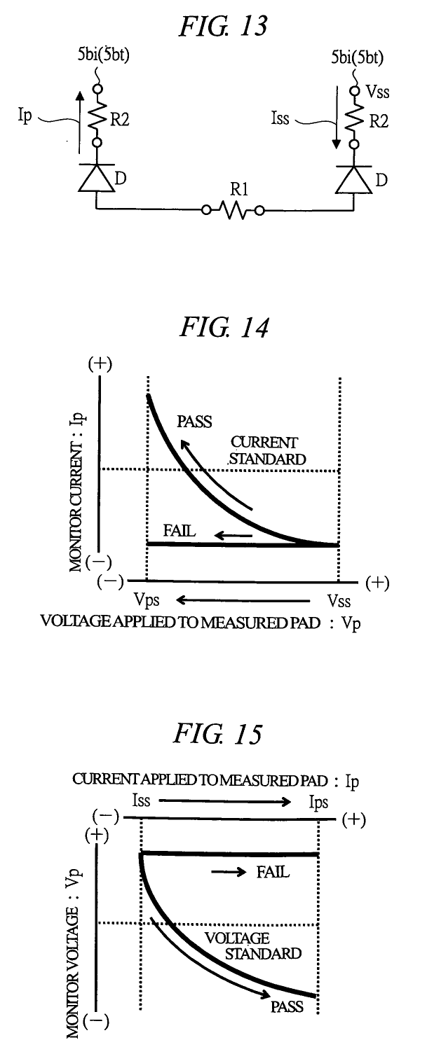

First of all, the principle of the open contact test will be described. FIG. 13 shows a DC equivalent circuit diagram of the circuit of the pad matrix wafer 1B at the time of the open contact test. FIG. 14 shows an explanatory diagram of the above-mentioned VFIM method at the time of the open contact test. FIG. 15 shows an explanatory diagram of the above-mentioned IFVM method at the time of the open contact test. The reference pad 5bi (or the pad 5bt) is fixed at the reference voltage (for example, the ground potential of 0V) Vcc and the reference current Iss (0 A). In this state, in the VFIM method as shown in FIG. 14, the current Ip flowing into the measured pad 5bi (or the pad 5bt) is measured while a bias (voltage Vp) applied to the measured pad 5bi (or the pad 5bt) is varied from the reference voltage Vss to a voltage Vps in the negative direction. If a certain amount of current Ip flows from the substrate 2b to the measured pad 5bi (or the pad 5bt) through the pn junction diode D, it can be consequently determined that the measured pad 5bi (or the pad 5bt) is not open (non-contact). Similarly, in the IFVM method as shown in FIG. 15, a voltage Vp at the measured pad 5bi (or the pad 5bt) is measured while a current Ip applied to the measured pad 5bi (or the pad 5bt) is varied from the reference current Iss to a current Ips in the positive direction. If the voltage Vp reaches a given level or higher, it can be determined that the measured pad 5bi (or the pad 5bt) is not open (non-contact). These tests make it possible to determine whether the probe 25 of the probe card makes good contact with the measured pad 5bi (or the pad 5bt). In addition, it is also possible to determine an optimum relative position relationship for the electrical connection between the probe card or the probe 25 and the pad 5bi (or the pad 5bt), that is, the height position coordinate of the probe card and probe 25 (the position coordinate in the direction vertical to the main surface of the pad matrix wafer 1B). Further, it is also possible to debug the probe card based on the measurements.

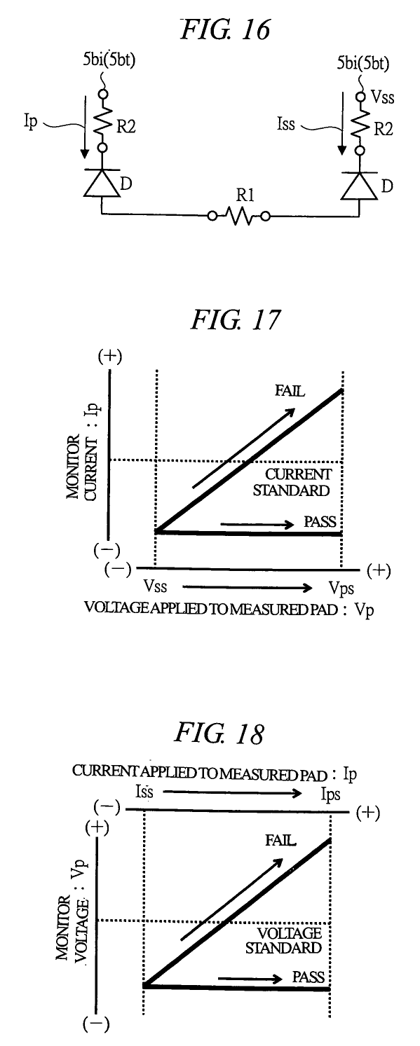

Next, the principle of the short contact test will be described. FIG. 16 shows a DC equivalent circuit diagram of the circuit of the pad matrix wafer 1B at the time of the short contact test. FIG. 17 shows an explanatory diagram of the above-mentioned VFIM method at the time of the short contact test. FIG. 18 shows an explanatory diagram of the above-mentioned IFVM method at the time of the short contact test. The reference pad 5bi (or the pad 5bt) is fixed to the reference voltage (for example, the ground potential of 0V) Vcc and the reference current Iss (0 A). In this state, in the VFIM method as shown in FIG. 17, a current Ip flowing into the measured pad 5bi (or the pad 5bt) is measured while the bias (voltage Vp) applied to the measured pad 5bi (or the pad 5bt) is varied from the reference voltage Vss to the voltage Vps in the positive direction. If the current Ip flows from the substrate 2b to the measured pad 5bi (or the pad 5bt) through the pn junction diode D, it can be consequently determined that the measured pad 5bi (or the pad 5bt) is short-circuited to other parts, and if not, it can be determined that the measured pad 5bi (or the pad 5bt) is not short-circuited to other parts. Similarly, in the IFVM method as shown in FIG. 18, the voltage Vp at the measured pad 5bi (or the pad 5bt) is measured while the current Ip applied to the measured pad 5bi (or the pad 5bt) is varied from the reference current Iss to the current Ips in the positive direction. If the voltage Vp is measured, it can be determined that the measured pad 5bi (or the pad 5bt) is short-circuited to other parts, and if not, it can be determined that the measured pad 5bi (or the pad 5bt) is not short-circuited to other parts. These tests make it possible to determine whether or not the measured pad 5bi (or the pad 5bt) is short-circuited to other parts.

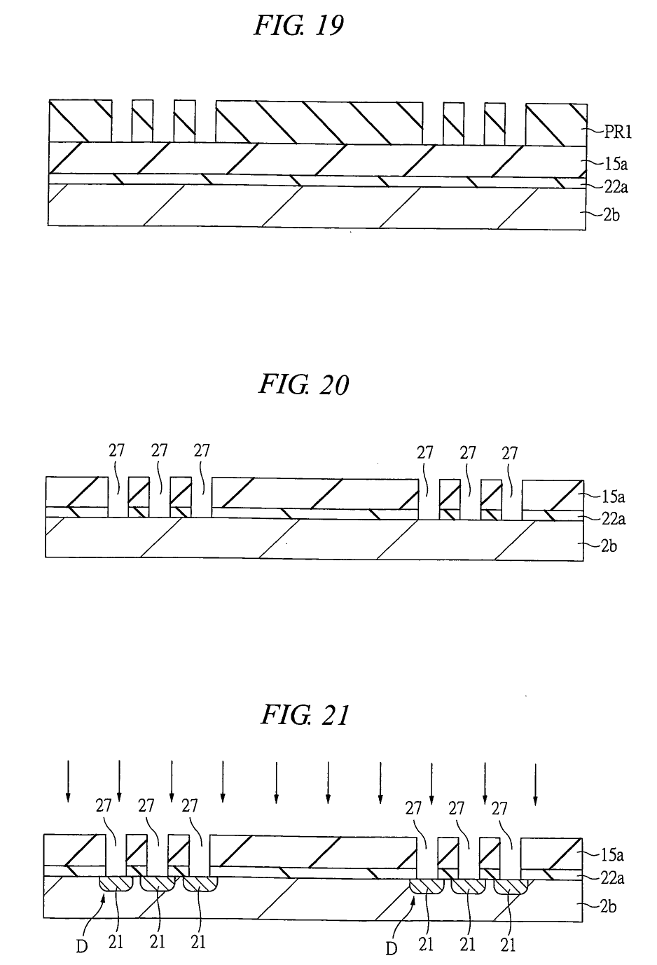

Next, an example of the manufacturing process (the pre-process) of the above-mentioned pad matrix wafer 1B will be described with reference to FIGS. 19 to 27. FIGS. 19 to 27 show cross-sectional views of the main part in the pre-process of the pad matrix wafer 1B.

First, ingot (substrate crystal) made of p-type silicon is cut to prepare the wafer for the pad matrix wafer 1B (wafer substrate 2b). In the first embodiment, the wafer for the pad matrix wafer 1B (wafer substrate 2b) is cut from an ingot different from the ingot for a wafer for the prototype wafer 1A. It is acceptable that the substrate 2b for the pad matrix wafer 1B is cut from the same ingot as that for the prototype wafer 1A. However, the ingot for the substrate 2a for the prototype wafer 1A is expensive because it is required to possess high device characteristics. On the other hand, the substrate 2b for the pad matrix wafer 1B is not required to possess high device characteristics equivalent to that of the substrate 2b of the prototype wafer 1A as long as it has a mechanical strength to hold a physical form and is capable of forming the pn junction. Then, the substrate 2b of the pad matrix wafer 1B is cut from an inexpensive ingot that is different from the ingot for the prototype wafer 1A. This reduces the cost of the semiconductor device.

Subsequently, as shown in FIG. 19, an insulating layer 22a made of, for example, silicon oxide is formed on the main surface of the p-type wafer substrate 2b by using the thermal oxidation method or the chemical vapor deposition (CVD) method. Thereafter, an insulating layer 15a made of, for example, silicon oxide is formed thereon by the CVD method. The insulating layer 15a can be formed of an insulating material with a lower dielectric constant than silicon oxide, instead of silicon oxide. The material of the insulating layer 15a is the same as that of the prototype wafer 1A and the product wafer. Next, on the insulating layer 15a, a photoresist film (hereinafter referred to as resist film) PR1 is formed by using the spin coating method, and then, a pattern of the resist film PR1 is formed through a series of photolithography processes such as exposure and development. The pattern of the resist film PR1 is used for forming a through hole, and has a shape so as to cover the regions other than the through holes forming region. In the exposure process, the mask to be used in the manufacturing process of the above-mentioned product is used.

Next, the insulating layers 15a and 22a are etched with using the resist film PR1 as an etching mask to remove parts of the insulating layers 15a and 22a exposed through the resist film PR1. By doing so, the through holes 27 are formed in the insulating layers 15a and 22a through which parts of the main surface of the substrate 2b can be exposed as shown in FIG. 20. Thereafter, as shown in FIG. 21, the resist film PR1 is removed, and then, impurities such as phosphorus (P) or arsenic (As) are introduced to the main surface of the substrate 2b via the through holes 27 by the ion-implantation method. In this manner, the n-type semiconductor regions 21 are formed in the main surface of the substrate 2b in a self-alignment manner with the through holes 27.

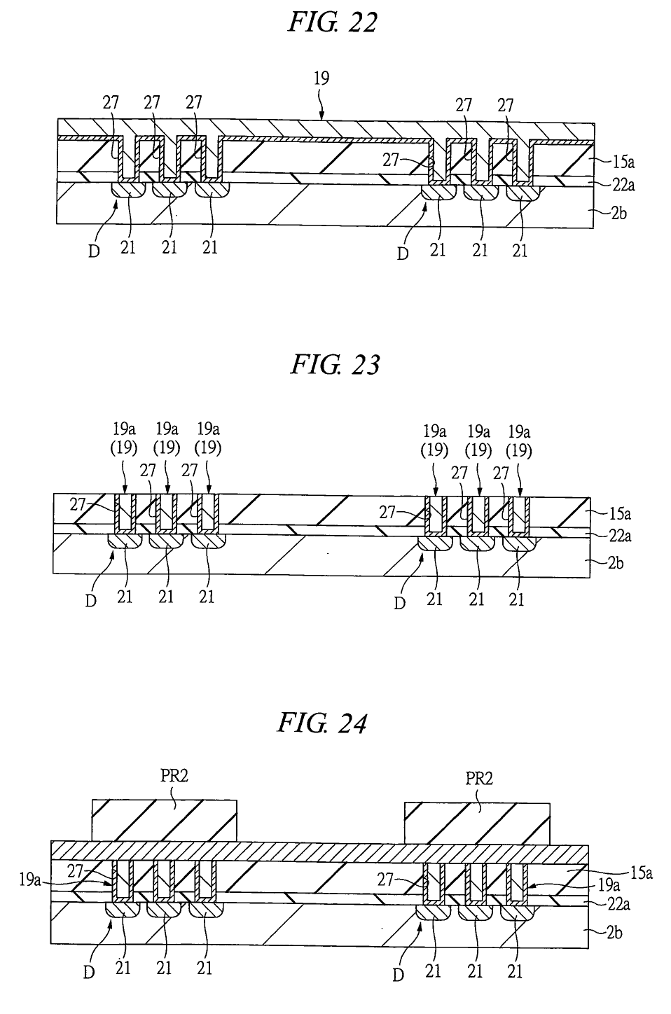

Next, as shown in FIG. 22, on the main surface of the substrate 2b, a titanium layer and a titanium nitride layer are formed in this order from below by the sputtering method. Further, a tungsten layer is formed thereon by the CVD method to form a conductive layer 19. Subsequently, the conductive layer 19 is polished by the chemical mechanical polishing (CMP) method to remove the conductive layer 19 on the insulating layer 15a. By doing so, plugs 19a are formed in the through holes 27 as shown in FIG. 23. The plugs 19a are electrically connected to the semiconductor regions 21.

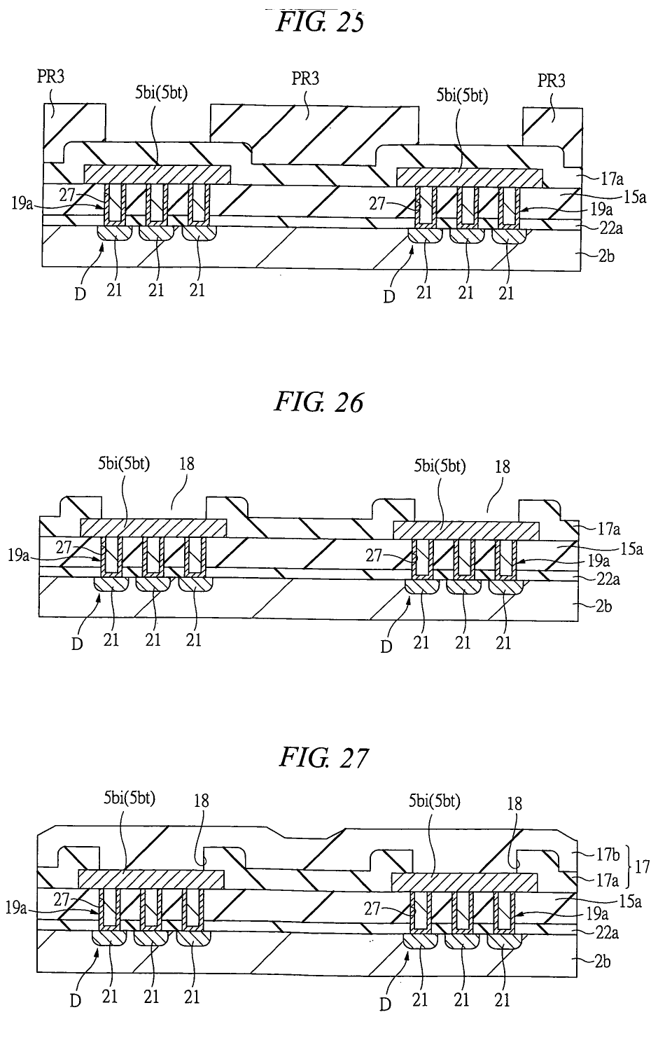

As shown in FIG. 24, on the main surface of the substrate 2b, a titanium layer, a titanium nitride layer, an aluminum layer, and a titanium nitride layer are formed in this order from below by the sputtering method to form a conductive layer 5. Thereafter, a resist film PR2 is formed on the conductive film 5 by the spin coating method. Then, a pattern of the resist film PR2 is formed through the photolithography processes. The pattern of the resist film PR2 is used for forming the pad and has a shape so as to cover the pad forming region. Also in the exposure process, the mask to be used in the manufacturing process of the above-mentioned product is used. Thereafter, the insulating layers 5 is etched with using the above-mentioned resist film PR2 as an etching mask to remove parts of the insulating layers 5 exposed through the resist film PR2. In this manner, a plurality of the pads 5bi and 5bt composed of the conductive layer 5 are formed as shown in FIG. 25.

Next, after the resist film PR2 is removed, a protective layer 17a made of, for example, silicon nitride is deposited on the main surface of the substrate 2b by the CVD method so as to cover the pads 5bi and 5bt, and then, patterns of a resist layer PR3 are formed thereon in the same manner as described above. The pattern of the resist film PR3 is used for forming the opening to expose parts of the pads 5bi and 5bt and has a shape so as to cover the regions other than the opening forming regions. Also in the exposure process, the mask to be used in the manufacturing process of the above-mentioned product is used.

Subsequently, the protective layer 17a is etched with using the resist film PR3 as an etching mask to remove parts of the protective layers 17a exposed through the resist film PR3. In this manner, the openings 18 are formed in the protective layer 17a, through which parts of the pads 5bi and 5bt can be exposed as shown in FIG. 26. Thereafter, after the resist film PR3 is removed, a protective layer 17b made of, for example, photosensitive polyimide resin is formed on the main surface of the substrate 2b by the spin coating method as shown in FIG. 27. Then, the openings 18 as shown in FIG. 8 are formed by the exposure and development processes performed directly to the protective layer 17b. Also in the exposure process, the mask to be used in the manufacturing process of the above-mentioned product is used. Thus, the pre-process of the pad matrix wafer 1B is completed.

As described above, in the first embodiment, all pre-processes of the pad matrix wafer 1B are completed before all pre-processes of the prototype wafer 1A are completed, and debugging such as inspection and assembly, condition setting, and evaluation after the pre-process of the prototype wafer 1A and product wafer can be performed by using the pad matrix wafer 1B. If these prerequisites are met, it is acceptable that the pad matrix wafer 1B and the prototype wafer 1A are placed and processed in the same lot during the processes where both wafers are subjected to the same processes (for example, the ion implantation process for forming the semiconductor region 21 of the pad matrix wafer 1B and the ion implantation process for forming the protective diodes Dp1 and Dp2 of the prototype wafer 1A, the process for forming the insulating layer 15a, the process for forming the openings in the insulating layer 15a, the process for forming the plugs 19a, and various photolithography processes). However, if a management system has so organized that both wafers are completed at the same time when the pad matrix wafer 1B and the prototype wafer 1A are placed in the same lot, it is preferable to place the pad matrix wafer 1B and the prototype wafer 1A into different lots.

In the following, an example of the methods of the above various condition settings and evaluations by using the pad matrix wafer 1B will be described.

First, data of planar position coordinates of the pad 5bi in the chip 4b and the pad 5bt in the TEG region on the pad matrix wafer 1B are created. In this process, coordinates at the tips of all or some probes are inputted while checking the tips of the probes of the probe cards with using images on a monitor screen. The coordinate data can be automatically recognized by positioning a pointer displayed on the monitor to the tip of the probe. Next, the coordinates of all or some pads 5bi (or the pads 5bt) are inputted while checking a typical chip 4b with using the images on the monitor screen. The coordinate data can be automatically recognized by positioning a rectangular frame called a polygon to the pad displayed on the monitor. Next, a relative positional relation between the coordinate of the tip of the probe and the coordinate of the pad 5bi (or the pad 5bt) is processed so as to match the positions of the probe and the pad 5bi (or the pad 5bt). Then, the probe is contacted on the pad 5bi (or the pad 5bt) to observe the trace of the probe left on the pad 5bi (or the pad 5bt) with using the images on the monitor and then to fine-adjust the position. Eventually, the coordinates of the tips of the probes, the coordinates of the pads 5bi (or the pads 5bt), and data of their relative positions are created.

Next, data (chip matrix data) of the planar position coordinate of the chip 4b of the pad matrix wafer 1B is created. In this process, the image that is a base point of the chip 4b is recognized while checking the image of the chip 4b with the monitor. The image data can be automatically recognized by positioning a pointer to the image displayed on the monitor. Subsequently, by inputting a chip size, the index size (one scale length in horizontal and vertical directions) is recognized. Next, based on the data obtained from the steps described above, the coordinates of all effective chips 4b are inputted while checking the images of the pad matrix wafer 1B with the monitor. During the input of the coordinates, the recognition by the use of the polygon which has the same dimensions as the chip size is performed along the outermost peripheral chips 4b of the pad matrix wafer 1B on the monitor. Therefore, all chips 4b including those inside the periphery are regarded as a region of effective chips 4b.

Next, after data of planar position coordinates of the pads 5bi and 5bt and chip matrix data are created, the pad 5bi (or the pad 5bt) of the chip 4b on the pad matrix wafer 1B is contacted to the probe of the probe card, and the above-mentioned open contact test and the short contact test are performed. Then, the distance between the position of the probe card (probe) and the position of the pad matrix wafer 1B in the direction vertical to the main surface of the pad matrix wafer 1B is fine-adjusted, and the evaluation and verification (verification for optimization of the contact between the pad 5bi (or the pad 5bt) and the probe) are executed, thereby creating the data of the optimum height position coordinate of the tip of the probe.

The coordinate data of the pad 5b thus created can be used as data of the coordinate of the pad of the wafer prober (planar coordinate of the pad 5at) in the measurement of a scribe test key in the wafer test process of the prototype wafer 1A and the product wafer. Also, the coordinate data of the pad 5bi can be used as data of the coordinate of the pad of the wafer prober (planar coordinate of the pad 5ai) in a probe test for the chips in the wafer test process of the prototype wafer 1A and product wafer. Further, the data of the optimum height position coordinate of the tip of the probe can be used as contact overdrive conditions of the probe card of the wafer prober (that is, optimum adjustment amount of the probe card (probe)) in the measurement of the scribe test key and the probe test for the chips in the wafer test process of the prototype wafer 1A and the product wafer. Also, the data obtained from the open contact test and the short contact test can be used, for example, for debugging the probe card. The debugging of the probe card refers to comparison and verification between the design value of the coordinates of the tip of the probe of the probe card and the actual measurements. In other words, by checking the pass between the probe card and the pad matrix wafer 1B in the open contact test and the short contact test, it is possible to verify whether the coordinate at the tip of probe of the probe card physically agrees with the coordinate of the pad 5bi and 5bt of the chip 4b, and whether a test head of a tester is conductive to the pad 5bi and 5bt of the chip 4b via the probe card. If the conditions above are not satisfied at this time, it is inevitable to re-design and re-produce the probe card. As a result, if the prototype wafer 1A is used to perform the debugging of the probe card, the delivery of the prototype is significantly delayed. Meanwhile, the first embodiment can debug the probe card by using the pad matrix wafer 1B before the pre-process of the prototype wafer 1A is completed, and therefore, the delivery time of the prototype can be substantially shortened.

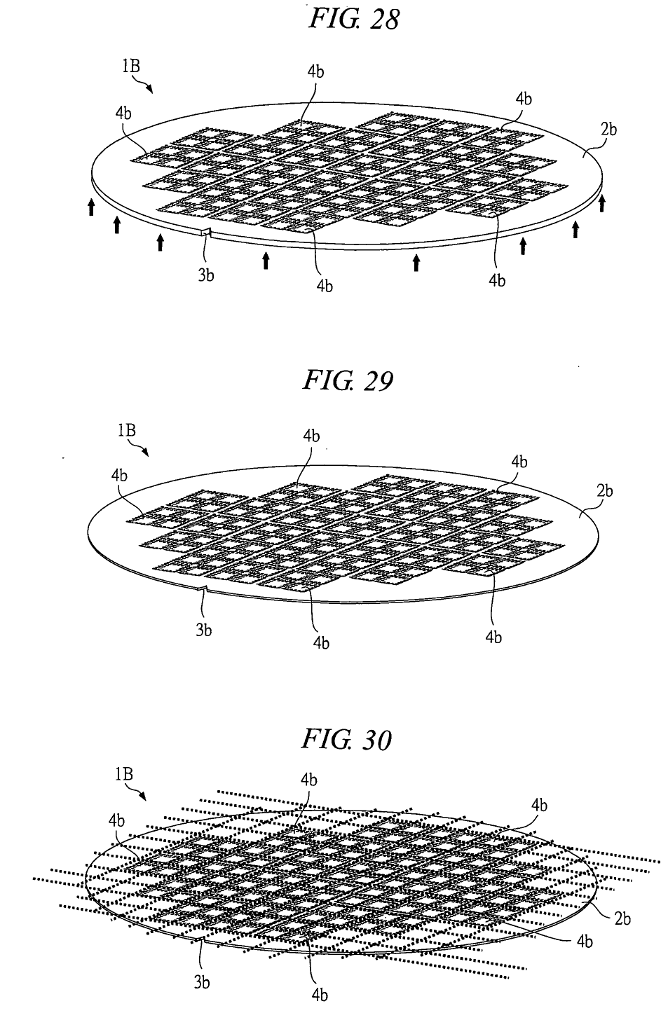

Next, the evaluation and condition setting of a rear surface polishing (back lapping or back grind) process are conducted by using the pad matrix wafer 1B. FIGS. 28 and 29 are general perspective views of the pad matrix wafer 1B before and after the rear surface polishing process. In this condition setting, data of optimum conditions for the rear surface polishing (for example, amount of polishing (polishing time), pressure, polishing material, polishing pad material, and others) to be used in the rear surface polishing process of the prototype wafer 1A and the product wafer are created by actually grinding or polishing the rear surface of the pad matrix wafer 1B.

Next, the evaluation and condition setting of a dicing process are performed by using the pad matrix wafer 1B. FIG. 30 is a general perspective view of the pad matrix wafer 1B after the dicing process. The lattice (broken lines) shows cut lines. In this condition setting, the data of optimum conditions for dicing (for example, the number of revolutions of a dicing blade, moving speed of the dicing blade) to be used in the dicing process of the prototype wafer 1A and the product wafer is created by actually cutting the cut region 6b of the pad matrix wafer 1B with using the dicing blade of a dicing saw.

Next, the evaluation and condition setting at the time of picking up the chip 4b are performed by using the pad matrix wafer 1B after the dicing process. In this condition setting, the data of optimum pick-up conditions (for example, vacuum suction, pressure of pin pressing the rear surface of the chip (optimum protrusive height)) to be used in the pick-up process of the chip after the dicing process of the prototype wafer 1A and the product wafer is created by actually picking up each chip 4b cut in the above-mentioned dicing process by the vacuum suction method.

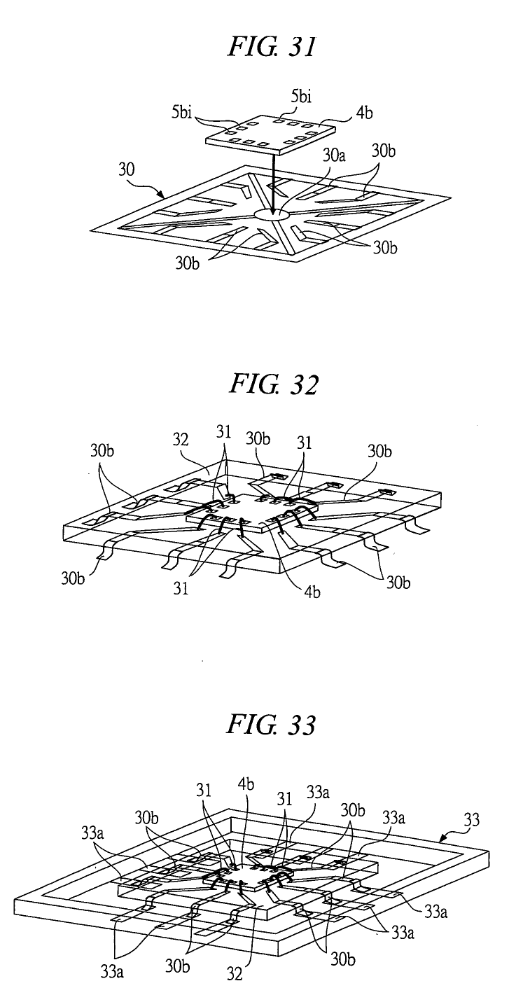

Next, the evaluation and condition setting at the time of bonding the chip 4b to the chip mounting region are performed by using the chip 4b cut from the pad matrix wafer 1B. FIG. 31 is a general perspective view showing an example when the chip 4b is mounted on the chip mounting region 30a of a lead frame 30. A reference numeral 30b denotes a lead. In this condition setting, the data of optimum bonding conditions (bonding position coordinate, bonding pressure, bonding material, coating amount of bonding material) to be used in a chip bonding process of the prototype wafer 1A and the product wafer is created by actually bonding the chip 4b to the chip mounting region 30a of the lead frame 30 by its rear surface.

Next, the evaluation and condition setting for connecting the chip 4b to the leads 30b of the lead frame 30 by the bonding wires are performed. FIG. 32 is a general perspective view showing an example of the state of the chip 4b after a wire-bonding process and an encapsulation process. A reference numeral 31 denotes a bonding wire and a reference numeral 32 denotes a resin-encapsulating member. In FIG. 32, the resin-encapsulating member 32 is transparent for making the inside thereof easy to see. In this condition setting, the data of optimum bonding conditions (bonding position coordinate, bonding pressure, height of wire loop) to be used in the wire-bonding process of the prototype wafer 1A and the product wafer is created by actually connecting the pads 5bi of the chip 4b to the lead 30a of the lead frame 30 with the bonding wires 31.

Next, the evaluation and condition setting for encapsulating the chip 4b are performed. In the condition setting, the data of the optimum encapsulating conditions (for example, viscosity of encapsulating resin material, temperature, encapsulating pressure) to be used in the encapsulating process of the chips of the prototype wafer 1A and the product wafer is created by actually encapsulating the chip 4b by using the resin-encapsulating member 32 made of epoxy-based resin. At the same time, the data for the lead cutting and molding after the encapsulating process are also created.

Next, the evaluation and condition setting of the contact conditions between the chip 4b after the encapsulating process and a package socket (final test conditions) are performed. FIG. 33 is a general perspective view showing an example in which the resin-encapsulating member 32 including the chip 4b is mounted on a package socket 33. Also in FIG. 33, the resin-encapsulating member 32 and the package socket 33 are transparent for making the inside thereof easy to see. A reference numeral 33a denotes a socket terminal. In the condition setting, the data of the optimum contact conditions of the package socket 33 to be used in the final test of the prototype wafer 1A and the product wafer is created by actually mounting the resin-encapsulating member 32 incorporating the chip 4b on the package socket 33. The condition setting and evaluation of the contact of the package socket using the chip 4b of the pad matrix wafer 1B are performed in the same manner as that of the open contact test and the short contact test described above.

Next, the method and steps for manufacturing the prototype will be described. Note that, since the method and steps for manufacturing the product are the same as those of the prototype, the description thereof is omitted.

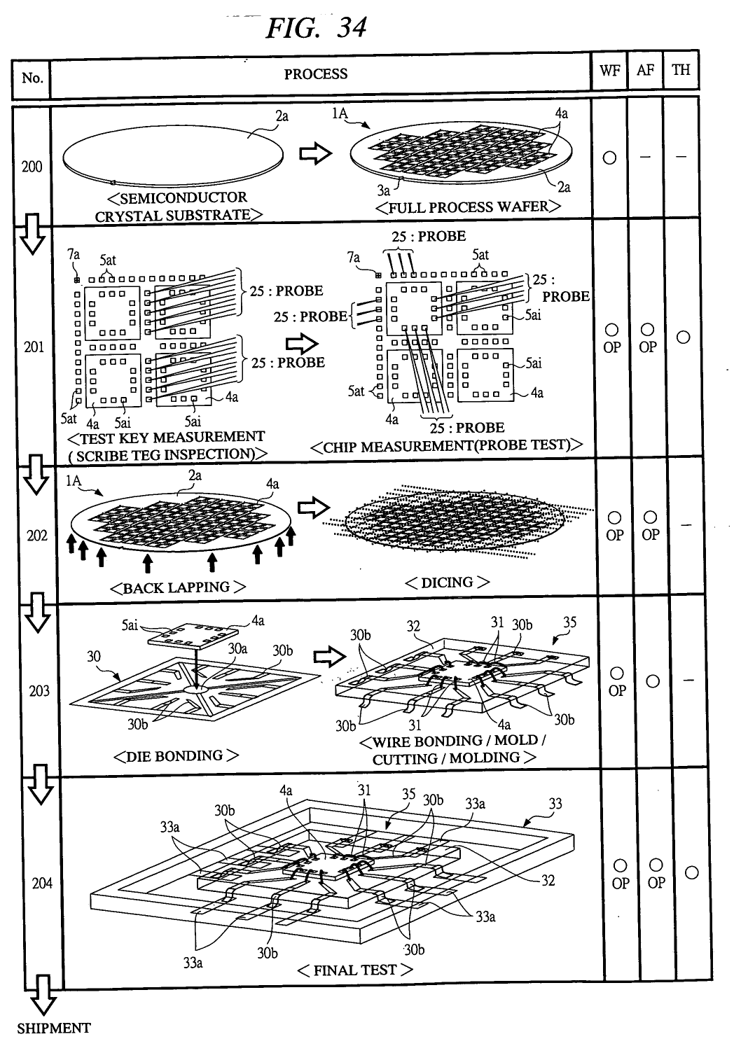

FIG. 34 shows an example of the processes and steps for manufacturing the prototype. A reference symbol OP denotes an option. First, in the pre-process (wafer fabrication) 200, an ingot made of p-type silicon is cut to prepare a wafer for the prototype wafer 1A (wafer substrate 2a). Then, chips are formed on the wafer in the same manner as the pre-process of the product wafer, thereby creating the prototype wafer (full process wafer) 1A. In general, the pre-process is performed in a wafer fab (wafer factory) WF, neither in an assembly fab (assembly factory) AF, nor in a test house TH.

Subsequently, in a wafer test process 201, a test key measurement and a chip measurement are sequentially performed by using a prober. In the test key measurement, inspection using the TEG is performed while the probes 25 of the prober are contacted to the pads 5at of the cut region 6a of the prototype wafer 1A. Also, in the chip measurement, it is checked whether the chips 4b are not defective while the probes 25 of the prober are contacted to the pads 5ai in the chips 4a of the prototype wafer 1A. In these measurements, the data of the pad and chip coordinates created by using the pad matrix wafer 1B are used. This wafer test process can be performed in any of the wafer fab WF, the assembly fab AF, and the test house TH. If the wafer test process is performed in the assembly fab AF or in the test house TH, the aforementioned various data obtained by using the pad matrix wafer 1B are offered to the assembly fab AF or the test house TH before performing the wafer test process for the prototype wafer 1A. Alternatively, the pad matrix wafer 1B itself is offered to the assembly fab AF or the test house TH to request them to determine the conditions for the test process. Thereafter, the prototype wafer 1A is offered to the assembly fab AF or the test house TH to request them to test the prototype wafer 1A under the test conditions obtained from the above-mentioned pad matrix wafer 1B. In this manner, the transition from the pre-process of the prototype wafer 1A to the wafer test can be made smoothly, and thus, it is possible to shorten the delivery time of the prototype wafer.

Thereafter, in the rear surface polishing process and dicing process 202, the rear surface of the prototype wafer 1A is ground and polished, and then, the cut region 6a of the prototype wafer 1A is cut with the dicing blade of a dicing saw to produce individual chips 4a. In these processes, the rear surface polishing and dicing conditions created by using the pad matrix wafer 1B are used. The rear surface polishing and dicing processes can be performed in either of the wafer fab WF or the assembly fab AF. If these processes are performed in the assembly fab AF, the data of the conditions of rear surface polishing and dicing obtained by using the pad matrix wafer 1B are offered to the assembly fab AF before performing the rear surface polishing process for the prototype wafer 1A. Alternatively, the pad matrix wafer 1B itself is offered to the assembly fab AF to request it to determine the conditions of he post-process. Thereafter, the prototype wafer 1A is offered o the assembly fab AF to request it to perform each process for the prototype wafer 1A under the various test conditions obtained from the pad matrix wafer 1B.

Thereafter, in an assembly process 203, after good chips 4a cut from the prototype wafer 1A are bonded on the chip mounting region 30a of the lead frame 30, a prototype 35 is fabricated through the wire bonding process, resin-encapsulating process, lead-cutting process and lead-molding process. In these processes, the chip bonding conditions, wire bonding conditions, resin-encapsulating conditions, and lead-cutting and molding conditions created by using the pad matrix wafer 1B are used. These processes can be performed in either the wafer fab WF or the assembly fab AF. If these processes are performed in the assembly fab AF, the data of the various conditions obtained by using the pad matrix wafer 1B are offered to the assembly fab AF before the assembly process of the prototype 35. Alternatively, the pad matrix wafer 1B itself is offered to the assembly fab AF to request it to determine the conditions for the post-process. Thereafter, the prototype wafer 1A is offered to the assembly fab AF to request it to perform each process for the prototype wafer 1A under the various test conditions obtained from the pad matrix wafer 1B.

Thereafter, in the final test process 204, a resin-encapsulating member 32 incorporating the chip 4a is mounted on a package socket, and an electrical test is performed to the prototype 35. In this process, the contact condition of the package socket created by using the chip 4b of the pad matrix wafer 1B is used. This process can be performed in any of the wafer fab WF, the assembly fab AF, and the test house TH. If the process is performed in the assembly fab AF or the test house TH, the data of the contact conditions of the package socket obtained by using the pad matrix wafer 1B are offered to the assembly fab AF or the test house TH before final test process of the prototype 35. Alternatively, the pad matrix wafer 1B itself is offered to the assembly fab AF or the test house TH to request them to determine the conditions for the test process. Thereafter, the prototype wafer 1A is offered to the assembly fab AF or the test house TH to request them to test the prototype wafer 1A under the various test conditions obtained from the pad matrix wafer 1B.

### Second Embodiment

In a second embodiment, an example of the case where the product chip has a damascene interconnect structure will be described.

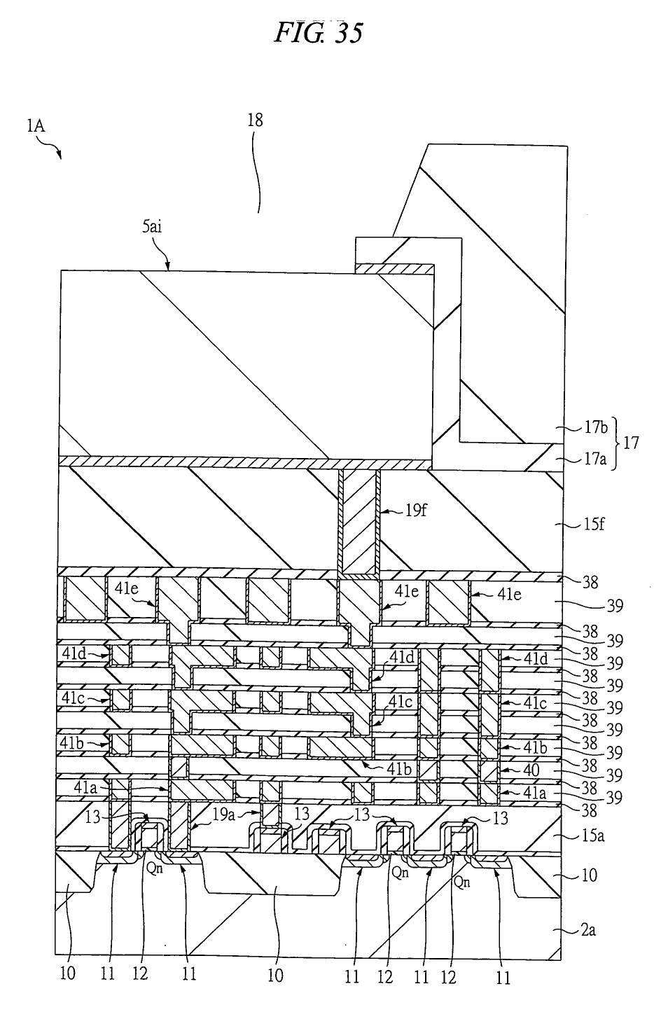

FIG. 35 illustrates a cross-sectional view of a main part of the chip 4a of the prototype wafer 1A. Since the planar configuration of the prototype wafer 1A in the second embodiment is the same as that in the first embodiment, the description thereof is omitted. Also, since the configuration of the product wafer in the second embodiment is the same as that of the prototype wafer 1A to be described in the second embodiment, the description thereof is omitted.

On the insulating layer 15a, a plurality of insulating layers 38 and 39 are alternately laminated. The insulating layer 38 is made of, for example, silicon nitride and the insulating layer 39 is made of, for example, silicon oxide. The insulating layer 39 can be formed of an insulating material with a dielectric constant lower than that of the silicon oxide. The insulating materials with a lower dielectric constant include, for example, a polyarylether (PAE)-based material such as SiLK (manufactured by The Dow Chemical Co., in US, relative dielectric constant=2.7, upper temperature limit=490° C. or higher, and withstand voltage=3.0 to 3.5 MV/Vm), or FLARE (manufactured by Honeywell Electronic Materials in US, relative dielectric constant=2.8 and upper temperature limit=400° C. or higher). Alternatively, SiOC-based material, SiOF-based material, HSQ (Hydrogen silsesquioxane)-based material, MSQ (methyl silsesquioxane)-based material, porous HSQ-based material, porous MSQ-based material, and porous organic material can be used instead of the PAE-based material. The SiOC-based material includes, for example, Black diamond (manufactured by Applied Materials, Inc. in US, relative dielectric constant=2.7 to 2.4 and upper temperature limit=450° C.) and CORAL (manufactured by Novellus Systems, Inc. in US, relative dielectric constant=2.7 to 2.4 and upper temperature limit=500° C.).

In the insulating layers 38 and 39, wiring openings such as holes and wiring grooves are formed, and plugs 40 and a plurality of wiring layers (buried wirings) 41a to 41e are formed by embedding conductors in the wiring openings. The lower wiring layers 41a and 41b are composed of conductors embedded in the wiring grooves, and formed by the single damascene method. That is, the wiring layers 41a and 41b are formed in such a way that, after forming the wiring grooves in the insulating layers 38 and 39, conductive layers are formed on the insulating layer 39 and in the wiring grooves, and the conductive layers are polished by the CMP method so that the conductive layers are left only in the wiring grooves. For example, tungsten is used as the main material of the wiring layer 41a, and the periphery thereof (side and bottom surfaces) is covered with a barrier metal layer formed of the laminated film of, for example, titanium and titanium nitride. For example, copper (Cu) is used as the main material of the wiring layer 41b, and the periphery thereof (side and bottom surfaces) is covered with a barrier metal layer formed of tantalum (Ta), tantalum nitride (TaN), or titanium nitride for preventing copper diffusion. The upper wiring layers 41c to 41e are composed of conductors embedded in the wiring grooves and the holes, and formed by the dual damascene method. That is, the wiring layers 41c to 41e are formed in such a way that, after the wiring grooves and the holes extending from the bottom of the wiring grooves to the lower wiring layers are formed in the insulating layers 38 and 39, conductive layers are formed on the insulating layer 39 and in the wiring grooves, and the conductive layers are polished by the CMP method so that the conductive layers are left only in the wiring grooves and the holes. The composition materials of the wiring layers 41c to 41e are the same as those of the wiring layer 41b.

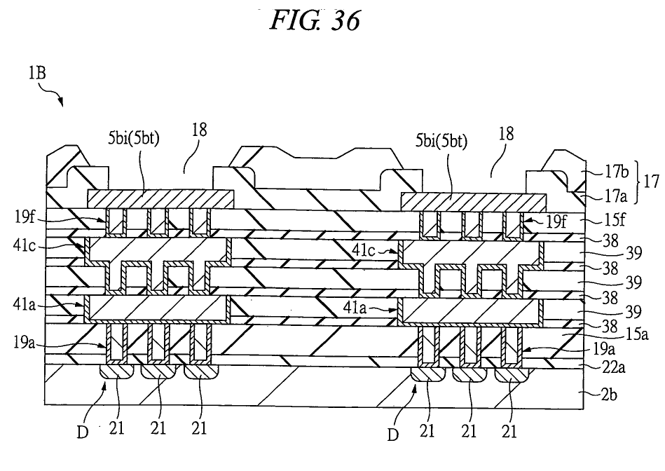

In the following, an example of the pad matrix wafer 1B in the case of a semiconductor device with such damascene interconnect structure will be described. FIG. 36 illustrates a cross-sectional view of the main part of the pad matrix wafer 1B in the second embodiment. The configuration of the pad matrix wafer 1B from the substrate 2b to the layer in which the plugs 19a are formed is the same as that in the first embodiment shown in FIG. 8. A three-layer wiring structure is exemplified here. The wiring layers 41a and 41c and the pads 5bi (or the pads 5bt) are provided in this order form below, and they are electrically connected to one another. The insulating layers 38 and 39 equivalent to those of the prototype and the product are formed. For example, if an insulating material with a lower dielectric constant is used as a material of the insulating layer 39 of the prototype and the product, the insulating layer 39 of the pad matrix wafer 1B is also formed of an insulating material with a lower dielectric constant. If the material of the insulting layer 39 is a low-dielectric constant insulating material, its bonding strength with substrates and other members is weaker than that of silicon oxide. Therefore, test and evaluation are required in advance about the bonding strength. In the second embodiment, evaluation and condition setting of a bonding strength between the insulating layer 39 made of a low-dielectric constant insulating material and other members (for example, the substrate 2b and wiring layers 41a to 41e) can be performed by using the pad matrix wafer 1B. Other than that, various condition settings and evaluations using the pad matrix wafer 1B and the method of manufacturing the prototype and the product by using the data obtained from the pad matrix wafer 1B are the same as those in the first embodiment. Therefore, the description thereof is omitted.

In the second embodiment, it is possible to shorten the lead time for shipment of the prototype even in the case where the product has the damascene interconnect structure. Therefore, the delivery time of semiconductor devices can be shortened.

### Third Embodiment

In the third embodiment, an example of the application in the case where a product chip is manufactured by using a wafer process package (hereinafter referred to as WPP) technique will be described. The WPP technique includes a step of collectively performing a package process at once for a plurality of chips on the wafer formed through the wafer process before dicing the wafer.

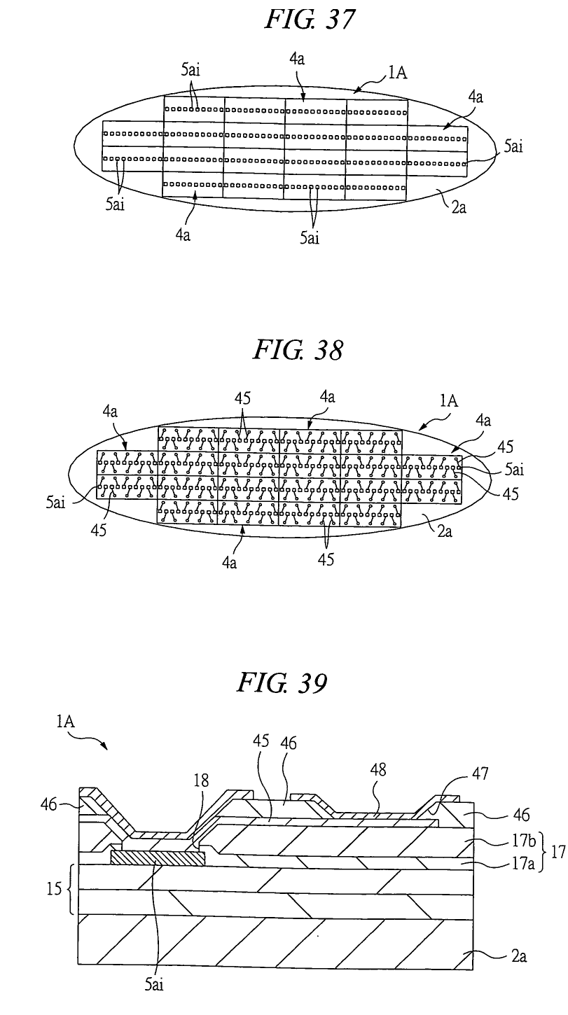

First, an example of manufacturing process of the prototype in the WPP will be described with reference to FIGS. 37 to 41. FIGS. 37 to 41 are explanatory diagrams of manufacturing process of the prototype in the WPP. Since the method for manufacturing the product is the same as that of the prototype, the description thereof is omitted.

FIG. 37 is a general plan view showing an example of the prototype wafer 1A after the pre-process. In this example, a plurality of the pads 5ai are arranged along the longitudinal center line of each chip 4a on the main surface of the prototype wafer 1A (a center pad arrangement).

FIG. 38 is a general plan view showing an example of the prototype wafer 1A after relocation wiring layer forming process. The relocation wirings 45 electrically connect the pads 5ai of the chips 4a to mounting electrodes such as bump electrodes for mounting the chips 4a on a predetermined wiring substrate, and have a function to achieve the matching between the dimension of the pad 5ai defined in the pre-process and that of the mounting electrode defined in the packaging process. In other words, since the dimensions of the mounting electrodes (dimension of electrode itself, distance between adjacent electrodes, and pitch) are determined by the dimensions of the wiring substrate, dimensions relatively larger than the dimension of the pad 5ai (dimension of the pad itself, distance between adjacent distance electrodes, and pitch) are required. For this reason, the pad 5ai with the fine dimensions determined by the pre-process cannot be used as the mounting electrode without any modification. Therefore, the pads 5ai are extended through the relocation wirings 45 to a relatively wider empty region in the main surface of the chip 4a to arrange the mounting electrodes with a relatively larger dimension in the region.

FIG. 39 is a cross-sectional view of the main part of the prototype wafer 1A shown in FIG. 38. The relocation wiring 45 is formed on the surface protection layer 17 and is electrically connected to the pad 5ai through an opening 18 formed in the surface protection layer 17. The relocation wiring 45 is formed by depositing a conductive layer for forming main wires such as copper on the barrier metal layer made of chrome. However, the material of the barrier metal layer of the relocation wirings 45 is not limited to chrome (Cr) but can be changed to various ones, for example, to titanium, titanium tungsten (TiW), titanium nitride, or tungsten. Also, an encapsulating resin layer 46 is formed on the surface protection layer 17 so as to cover the relocation wirings 45. The encapsulating resin layer 46 is made of, for example, photosensitive polyimide resin. Openings 47 are formed in some parts of the encapsulating resin layer 46, and a bump substrate metal layer 48 is electrically connected to the relocation wirings 45 through the opening 47. The bump substrate metal layer 48 is formed by depositing, for example, chrome, chrome-copper alloy, and gold (Au) in this order from below. Note that although wiring layers are formed in the insulating layer 15 similar to FIGS. 5 and 35 shown above, they are omitted for making the drawing easy to see.

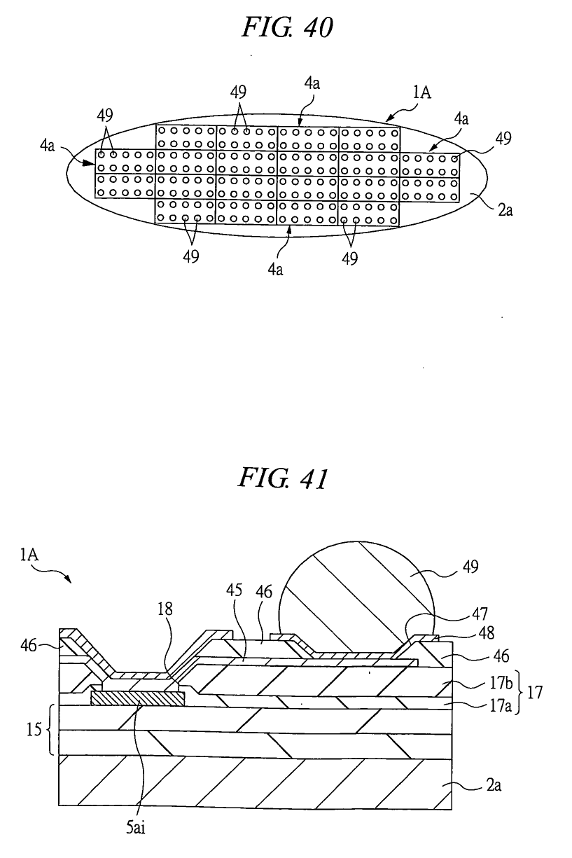

Next, FIG. 40 is a general plan view showing an example of the prototype wafer 1A after a solder bump electrode forming process. FIG. 41 shows a cross-sectional view of the main part of the prototype wafer 1A shown in FIG. 40. The solder bump electrode 49 is a protruding electrode made of, for example, lead or tin, and is electrically connected to the bump substrate metal layer 48.

After the processes described above, the chips 4a are cut from the prototype wafer 1A through the rear surface polishing and dicing processes. Each chip 4a has already had a chip size package (CSP) structure. Subsequently, the chip 4a is mounted on a wiring substrate. At this time, the surface on which the solder bump electrodes are formed is faced to the wiring substrate to bond the solder bump electrodes 49 of the chip 4a to the land of the wiring substrate. By doing so, the solder bump electrodes 49 and the land of the wiring substrate are electrically connected to each other (flip chip bonding).

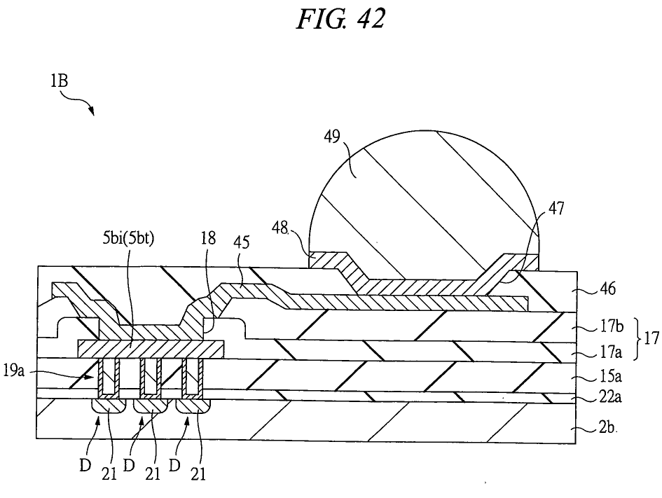

In the following, an example of the pad matrix wafer 1B used when the product chips are manufactured by using the WPP technique will be described. FIG. 42 is a cross-sectional view of the main part of the pad matrix wafer 1B in the third embodiment. The configuration from the substrate 2b to the surface protection layer 17 in the pad matrix wafer 1B is the same as that described in the first embodiment shown in FIG. 8. The relocation wirings 45 are formed on the surface protection layer 17. The relocation wirings 45 are electrically connected to the pads 5bi (or the pad 5bt) through the openings 18. The encapsulating resin layer 46 is formed on the surface protection layer 17 so as to cover the relocation wiring 45. The bump substrate metal layer 48 is formed on the encapsulating resin layer 46. The bump substrate metal layer 48 is electrically connected to the relocation wiring 45 through the opening 47. The solder bump electrode 49 is formed on the bump substrate metal layer 48. In the third embodiment, the condition setting and evaluation of the flip chip bonding can be performed by using the pad matrix wafer 1B. Other than that, various condition settings and evaluations using the pad matrix wafer 1B and a method of manufacturing the prototype and the product by using the data obtained from the pad matrix wafer 1B are the same as those of the first embodiment. Therefore, the description thereof is omitted.

According to the third embodiment, it is possible to shorten a lead time for shipment of the prototype even if the WPP technique is used in the manufacturing process of the product, and therefore, it is possible to shorten the delivery time of semiconductor devices.

In the foregoing, the invention made by the inventors of the present invention has been concretely described based on the embodiments. However, it is needless to say that the present invention is not limited to the foregoing embodiments and various modifications and alterations can be made within the scope of the present invention.

The cases where a wire bonding method is used as a method of electrically connecting the chips and the mounting members (a lead frame and a wiring substrate) have been described in the first and second embodiments. However, a method is not limited to the wire bonding method, but the flip chip bonding method in which the chip and the mounting substrate are electrically connected through a bump electrode may be used instead. In this case, the solder bump electrodes 49 are connected to the pads 5ai of the chip 2a and to the pads 5bi of the chip 2b via the pad substrate metal layer 48.

In addition, the case where the present invention is applied to a method of manufacturing a semiconductor device in which one chip is encapsulated in one package has been described in the first to third embodiments. However, other than the cases described above, the invention may also be applied to a method of manufacturing a semiconductor device in which a plurality of chips are encapsulated in one package such as system in package (SIP) or a module to configure a desired system in one package. In this case, since condition setting and evaluation used in a process where a plurality of chips constituting a system are assembled can be performed in advance, the lead time for shipment of the prototype can be significantly shortened and thus the delivery time of the semiconductor device can be significantly shortened.

The present invention is preferably applied to a product having pads of a chip whose pitch is narrow, having a large number of pads, and whose pad arrangement is often modified.

In the foregoing, the cases where the invention made by the inventors of the present invention is applied mainly to a method of manufacturing a semiconductor device which is an application field derived from the background of the invention have been described. The invention, however, is not limited to that method but is also applicable to various cases. For example, the present invention can be applied to a method of manufacturing a liquid crystal device and micromachine.

The present invention can be applied to a manufacturing industry of semiconductor devices.

1. A manufacturing method of a semiconductor device, comprising the step of:
prior to a post-process or a test process of a first wafer having chips and external terminals formed by the same pre-process as that of a product wafer, determining manufacturing conditions of said post-process or said test process by using a second wafer having chips formed by a pre-process whose number of steps are fewer than that of the pre-process of said first wafer and having chips and external terminals arranged in the same manner as those of said first wafer.

2. The manufacturing method of a semiconductor device according to claim 1,
wherein the pre-process of said second wafer comprises: the step of forming a semiconductor region where pn junctions are formed in said second wafer; or the step of forming wires on said second wafer, or comprises: both of said steps.

3. The manufacturing method of a semiconductor device according to claim 1,
wherein the manufacturing conditions created by using said second wafer include data of planar position coordinates of said external terminals or planar position coordinates of said chips, or planar position coordinates of both of them.

4. The manufacturing method of a semiconductor device according to claim 1,
wherein the manufacturing conditions created by using said second wafer include data of height position coordinates of a probe of a probe card to be used in said wafer test of said first wafer.

5. The manufacturing method of a semiconductor device according to claim 4,
wherein said data of height position coordinates of said probe is created based on electrical measurements obtained by applying a bias to the pn junction area formed on said second wafer.

6. The manufacturing method of a semiconductor device according to claim 1,
wherein the post-process of said first wafer is performed by using said manufacturing conditions created by using said second wafer.

7. The manufacturing method of a semiconductor device according to claim 6,
wherein said manufacturing conditions created by using said second wafer include data of processing conditions to be used in a dicing process and/or a rear surface polishing process of said first wafer.

8. The manufacturing method of a semiconductor device according to claim 6,
wherein said manufacturing conditions created by using said second wafer include data of processing conditions to be used in a pick-up process of chips cut from said first wafer, a bonding process of the chips cut from said first wafer, a bonding process of external terminals of the chips cut from said first wafer, or an encapsulating process of the chips cut from said first wafer, or in two or more processes selected from among these processes.

9. The manufacturing method of a semiconductor device according to claim 6,
wherein said manufacturing conditions created by using said second wafer include data to be used when testing packaged chips after the chips cut from said first wafer are encapsulated.

10. The manufacturing method of a semiconductor device according to claim 9,
wherein said data is created based on the electrical measurements obtained by applying a bias to the pn junction area formed on said second wafer.

11. A manufacturing method of a semiconductor device, comprising the steps of:
(a) preparing a first wafer whose pre-process is completed through the same pre-process as that of a product wafer; and
(b) preparing a second wafer contributing to creating manufacturing conditions to be used in processes subsequent to the pre-process of said first wafer before the completion of the pre-process of said first wafer.

12. A manufacturing method of a semiconductor device, comprising the steps of:
(a) preparing a first wafer whose pre-process is completed through the same pre-process as that of a product wafer;
(b) preparing a second wafer contributing to creating manufacturing conditions to be used in processes subsequent to the pre-process of said first wafer before the completion of the pre-process of said first wafer;
(c) creating manufacturing conditions to be used in processes subsequent to the pre-process of said first process by using said second wafer;
(d) performing various processes for said first wafer in the processes subsequent to the pre-process by using said manufacturing conditions created by using said second wafer, thereby manufacturing a prototype; and
(e) forming chips for a product on a third wafer based on said prototype.

13. The manufacturing method of a semiconductor device according to claim 14,
wherein the chips and the external terminals of said first, second, and third wafers are arranged in the same manner.

14. A manufacturing method of a semiconductor device,
wherein, before fabrication of a first wafer having chips and external terminals formed by the same pre-process as that of a product wafer is completed in a first manufacturing company, the first manufacturing company sends a second manufacturing company or a testing company a second wafer having chips formed by a pre-process whose number of steps are fewer than that of the pre-process of said first wafer and having chips and external terminals arranged in the same manner as those of said first wafer,
the first manufacturing company requests them to determine conditions of assembly process and/or test process of said first wafer, and
the first manufacturing company sends said first wafer to the second manufacturing company or the testing company to request them to assemble and/or test said first wafer by using said assembly and/or test conditions.

15. A manufacturing method of a semiconductor device,
wherein, before fabrication of a first wafer having chips and external terminals formed by the same pre-process as that of a product wafer is completed in a first manufacturing company, a second manufacturing company or a testing company acquires a second wafer having chips formed by a pre-process whose number of steps are fewer than that of the pre-process of said first wafer and having chips and external terminals arranged in the same manner as those of said first wafer,
the second manufacturing company or the testing company determine conditions of assembly process and/or test process of said first wafer, and
the second manufacturing company or the testing company assemble and/or test said first wafer offered by said first manufacturing company by using said assembly and/or test conditions.
